(19) United States
(12) Patent Application Publication
(10) Pub. No.: US 2025/0311105 A1
(43) Pub. Date: Oct. 2, 2025

(54) PRINTED CIRCUIT BOARD AND ELECTRONIC CONTROL DEVICE

(71) Applicant: DENSO CORPORATION, Kariya-city (JP)

(72) Inventors: Masato IMAMURA, Kariya-city (JP); Tetsuya OISHI, Kariya-city (JP)

(21) Appl. No.: 19/076,257

(22) Filed: Mar. 11, 2025

(30) Foreign Application Priority Data
Mar. 27, 2024 (JP) 2024-051450

(51) Int. Cl. H05K 1/11; H05K 1/02; H05K 1/18

(52) U.S. Cl. CPC H05K 1/115; H05K 1/0298; H05K 1/18; H05K 2201/09518; H05K 2201/10015

(57) ABSTRACT

A printed circuit board includes a plurality of dielectric layers, a plurality of conductive pattern layers alternately laminated with the plurality of dielectric layers, a through hole penetrating through the plurality of the dielectric layers, a through via penetrating through the plurality of dielectric layers, and an inner layer via. The inner layer via penetrates through each dielectric layer from an Mth dielectric layer to the (N-1)th dielectric layer, where M is an integer that is greater than or equal to two and less than or equal to (N−1), and has an inner circumferential surface on which an inner layer via conductor is disposed. The through via and the inner layer via are connected to each other with at least one conductive pattern layer that is selected from a second conductive pattern layer to an (N-1)th conductive pattern layer in the plurality of conductive pattern layers.

### CROSS REFERENCE TO RELATED APPLICATION

The present application claims the benefit of priority from Japanese Patent Application No. 2024-051450 filed on Mar. 27, 2024. The entire disclosure of the above application is incorporated herein by reference.

### TECHNICAL FIELD

The present disclosure relates to a printed circuit board and an electronic control device.

### BACKGROUND

When connecting a printed circuit board and terminals of an electronic component by soldering, heat generated during soldering is not easily transferred to a rear surface, which may result in poor solderability. If the solderability is poor, thermal stress can result in cracks in the solder. When these cracks gradually increase, the electrical connection can eventually be lost, leading to failure.

### SUMMARY

The present disclosure provides a printed circuit board. According to one example, the printed circuit board includes a plurality of dielectric layers from a first dielectric layer to an (N-1)th dielectric layer, where N is an integer that is greater than or equal to three, a plurality of conductive pattern layers from a first conductive pattern layer to an Nth conductive pattern layer, a through hole, a through via, and an inner layer via.

The plurality of conductive pattern layers from the first conductive pattern layer to the Nth conductive pattern layer are laminated alternately with the plurality of dielectric layers in such a manner that the first conductive pattern layer is disposed above the first dielectric layer and the (N-1)th dielectric layer is disposed above the Nth conductive pattern layer. The through hole penetrates through the plurality of dielectric layers from the first dielectric layer to the (N-1)th dielectric layer, and has an inner circumferential surface on which a through hole conductor is disposed. A terminal of a mounted component is to be inserted into the through hole in a state where the mounted component is mounted above the first conductive pattern layer.

The through via penetrates through the plurality of dielectric layers from the first dielectric layer to the (N-1)th dielectric layer, and has an inner circumferential surface on which a through via conductor is disposed. The through via is connected to the through hole with at least one conductive pattern layer that is selected from the first conductive pattern layer to an (N-1)th conductive pattern layer.

The inner layer via penetrates through each dielectric layer from an Mth dielectric layer to the (N-1)th dielectric layer in the plurality of dielectric layers, where M is an integer that is greater than or equal to two and less than or equal to (N-1), and has an inner circumferential surface on which an inner layer via conductor is disposed.

The through via and the inner layer via are connected to each other with at least one conductive pattern layer that is selected from an Mth conductive pattern layer to the (N-1)th conductive pattern layer in the plurality of conductive pattern layers.

The present disclosure also provides an electronic control device including a mounted component and the above-described printed circuit board on which the mounted component is mounted.

### BRIEF DESCRIPTION OF DRAWINGS

Objects, features and advantages of the present disclosure will become apparent from the following detailed description made with reference to the accompanying drawings. In the drawings:

FIG. 1 is a block diagram showing a configuration of an electronic control device;

FIG. 2 is a cross-sectional view showing a configuration of a printed circuit board according to a first embodiment;

FIG. 3 is a diagram showing a shape of a conductive pattern layer on a mounting surface;

FIG. 4 is a diagram showing a shape of a conductive pattern layer on a dielectric layer inside the printed circuit board;

FIG. 5 is a diagram showing a shape of a conductive pattern layer on a soldering surface; and

FIG. 6 is a cross-sectional view showing a configuration of a printed circuit board according to a second embodiment.

### DETAILED DESCRIPTION

In a printed circuit board, a plurality of vias may be arranged around through holes into which terminals of an electronic component are inserted so that heat generated during soldering can be efficiently transferred to a rear surface.

However, after detailed study by the present inventors, it was found that increasing the number of through vias to improve thermal efficiency increases the number of situations in which wiring patterns must be arranged to avoid the through vias, which may reduce the freedom in wiring pattern arrangement on the printed circuit board (that is, the freedom to design artwork).

A printed circuit board according to a first aspect of the present disclosure includes a plurality of dielectric layers from a first dielectric layer to an (N-1)th dielectric layer, where N is an integer that is greater than or equal to three, a plurality of conductive pattern layers from a first conductive pattern layer to an Nth conductive pattern layer, a through hole, a through via, and an inner layer via.

The plurality of conductive pattern layers from the first conductive pattern layer to the Nth conductive pattern layer are laminated alternately with the plurality of dielectric layers in such a manner that the first conductive pattern layer is disposed above the first dielectric layer and the (N-1)th dielectric layer is disposed above the Nth conductive pattern layer. The through hole penetrates through the plurality of dielectric layers from the first dielectric layer to the (N-1)th dielectric layer, and has an inner circumferential surface on which a through hole conductor is disposed. A terminal of a mounted component is to be inserted into the through hole in a state where the mounted component is mounted above the first conductive pattern layer.

The through via penetrates through the plurality of dielectric layers from the first dielectric layer to the (N-1)th dielectric layer, and has an inner circumferential surface on which a through via conductor is disposed. The through via is connected to the through hole by at least one conductive pattern layer that is selected from the first conductive pattern layer to an (N-1)th conductive pattern layer.

The inner layer via penetrates through each dielectric layer from an Mth dielectric layer to the (N-1)th dielectric layer in the plurality of dielectric layers, where M is an integer that is greater than or equal to two and less than or equal to (N-1), and has an inner circumferential surface on which an inner layer via conductor is disposed.

The through via and the inner layer via are connected to each other with at least one conductive pattern layer that is selected from an Mth conductive pattern layer to the (N-1)th conductive pattern layer in the plurality of conductive pattern layers.

The printed circuit board of the first aspect configured in this manner has the inner layer via connected to the through via, thereby increasing the number of paths for conducting heat between the first conductive pattern layer and the Nth conductive pattern layer, and improving the thermal efficiency of the printed circuit board.

Furthermore, in the printed circuit board of the first aspect, the inner layer via penetrates each dielectric layer from any one of the dielectric layers selected from the second dielectric layer to the (N-1)th dielectric layer to the (N-1)th dielectric layer. Therefore, the printed circuit board of the first aspect can change the number of dielectric layers through which the inner vias penetrates and the arrangement of the inner via according to the wiring pattern in the printed circuit board. Accordingly, the printed circuit board of the first aspect can ensure the freedom in wiring pattern arrangement.

As described above, the printed circuit board of the first aspect can improve the thermal efficiency of the printed circuit board while ensuring the freedom in wiring pattern arrangement.

An electronic control device according to a second aspect of the present disclosure includes a mounted component and a printed circuit board on which the mounted component is mounted. The printed circuit board includes a plurality of dielectric layers from a first dielectric layer to an (N-1)th dielectric layer, where N is an integer that is three or greater, a plurality of conductive pattern layers from a first conductive pattern layer to an Nth conductive pattern layer, a through hole, a through via, and an inner layer via. The through via and the inner layer via are connected to each other with at least one conductive pattern layer that is selected from the second conductive pattern layer to the (N-1)th conductive pattern layer in the plurality of conductive pattern layers.

The electronic control device of the second aspect configured as described above includes the printed circuit board of the first aspect, and can obtain the same effects as the printed circuit board of the first aspect.

### First Embodiment

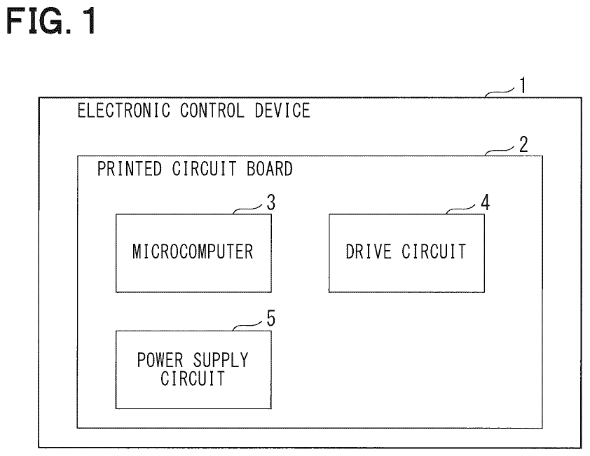

Hereinafter, a first embodiment according to the present disclosure will be described with reference to the drawings. An electronic control device 1 of the present embodiment is a device that controls a controlled object (not shown), and includes a printed circuit board 2 as shown in FIG. 1. The electronic control device 1 is configured by housing the printed circuit board 2 in a housing (not shown).

On the printed circuit board 2, a microcomputer 3, a drive circuit 4 and a power supply circuit 5 are mounted. The microcomputer 3 executes various control processes for controlling the controlled object, and outputs a control signal indicating a control amount for controlling the controlled object to the drive circuit 4.

Based on the control signal from the microcomputer 3, the drive circuit 4 outputs a drive signal for driving the controlled object to the controlled object. The power supply circuit 5 is a circuit that generates a predetermined power supply voltage for operating the microcomputer 3 and the drive circuit 4.

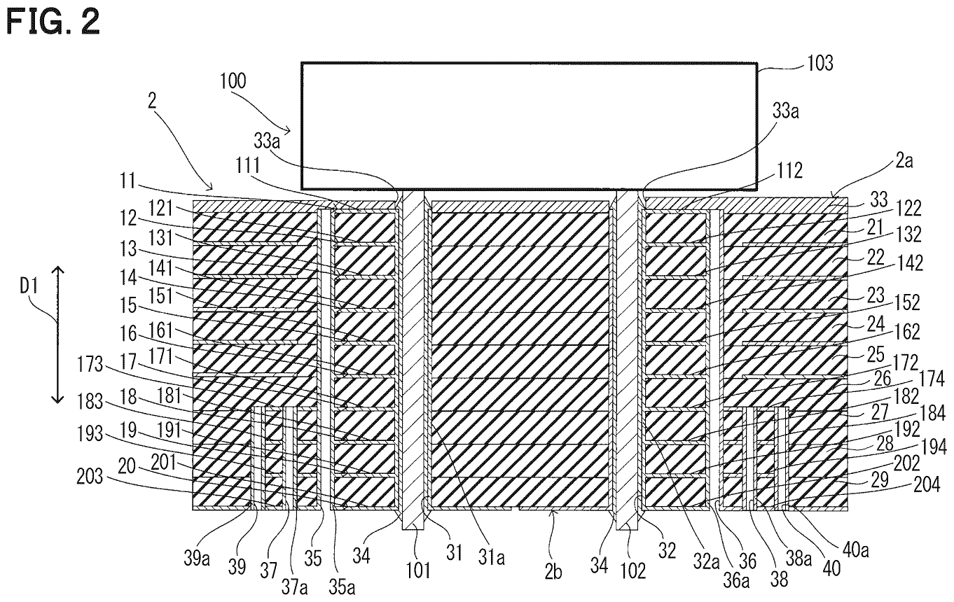

As shown in FIG. 2, the printed circuit board 2 includes ten conductive pattern layers 11, 12, 13, 14, 15, 16, 17, 18, 19, and 20, and nine dielectric layers 21, 22, 23, 24, 25, 26, 27, 28, and 29. The printed circuit board 2 is formed by laminating the ten conductive pattern layers 11 to 20 and the nine dielectric layers 21 to 29 alternately along a laminating direction D1.

Therefore, the conductive pattern layer 11 is disposed on the dielectric layer 21. The conductive pattern layer 12 is disposed between the dielectric layer 21 and the dielectric layer 22. The conductive pattern layer 13 is disposed between the dielectric layer 22 and the dielectric layer 23. The conductive pattern layer 14 is disposed between the dielectric layer 23 and the dielectric layer 24. The conductive pattern layer 15 is disposed between the dielectric layer 24 and the dielectric layer 25. The conductive pattern layer 16 is disposed between the dielectric layer 25 and the dielectric layer 26. The conductive pattern layer 17 is disposed between the dielectric layer 26 and the dielectric layer 27. The conductive pattern layer 18 is disposed between the dielectric layer 27 and the dielectric layer 28. The conductive pattern layer 19 is disposed between the dielectric layer 28 and the dielectric layer 29. The dielectric layer 29 is disposed on the conductive pattern layer 20.

The printed circuit board 2 is formed with a positive electrode terminal through hole 31 into which a positive electrode terminal 101 of a capacitor 100 is inserted, and a negative electrode terminal through hole 32 into which a negative electrode terminal 102 of the capacitor 100 is inserted. The capacitor 100 is, for example, a component of the power supply circuit 5. In the present embodiment, the capacitor 100 is an aluminum electrolytic capacitor.

The positive electrode terminal through hole 31 and the negative electrode terminal through hole 32 are formed so as to penetrate through the dielectric layers 21 to 29. A conductor 31a is formed over the entire inner circumferential surface of the positive electrode terminal through hole 31. In addition, a conductor 32a is formed over the entire inner circumferential surface of the negative electrode terminal through hole 32. Hereinafter, the conductor 31a and the conductor 32a will be referred to as a positive electrode terminal through hole conductor 31a and a negative electrode terminal through hole conductor 32a, respectively.

The printed circuit board 2 includes a solder resist 33. The solder resist 33 is disposed on the conductive pattern layer 11 and on a region of the dielectric layer 21 where the conductive pattern layer 11 is not disposed. However, the solder resist 33 is arranged so as not to cover openings of the positive electrode terminal through hole 31 and the negative electrode terminal through hole 32. As a result, resist openings 33a are formed so that the openings of the positive electrode terminal through hole 31 and the negative electrode terminal through hole 32 are exposed.

The positive electrode terminal 101 and the negative electrode terminal 102 of the capacitor 100 are conductors each formed in a linear shape. The positive electrode terminal 101 and the negative electrode terminal 102 are inserted into the positive electrode terminal through hole 31 and the negative electrode terminal through hole 32 from the resist openings 33a, respectively. End portions of the positive electrode terminal 101 and the negative electrode terminal 102 protrude from the openings of the positive electrode terminal through hole 31 and the negative electrode terminal through hole 32 on a surface of the printed circuit board 2 opposite to a surface on which the resist openings 33a are formed.

Of the two surfaces of the printed circuit board 2 formed in a plate shape, the surface on which a body portion 103 of the capacitor 100 is disposed is hereinafter referred to as a mounting surface 2a. Of the two surfaces of the printed circuit board 2, the surface from which the end portions of the positive electrode terminal 101 and the negative electrode terminal 102 of the capacitor 100 protrude is referred to as a soldering surface 2b.

With the positive electrode terminal 101 and the negative electrode terminal 102 of the capacitor 100 inserted into the positive electrode terminal through hole 31 and the negative electrode terminal through hole 32, respectively, the capacitor 100 is fixed to the printed circuit board 2 by filling a space between the positive electrode terminal 101 and the positive electrode terminal through hole 31, and a space between the negative electrode terminal 102 and the negative electrode terminal through hole 32 with a solder 34.

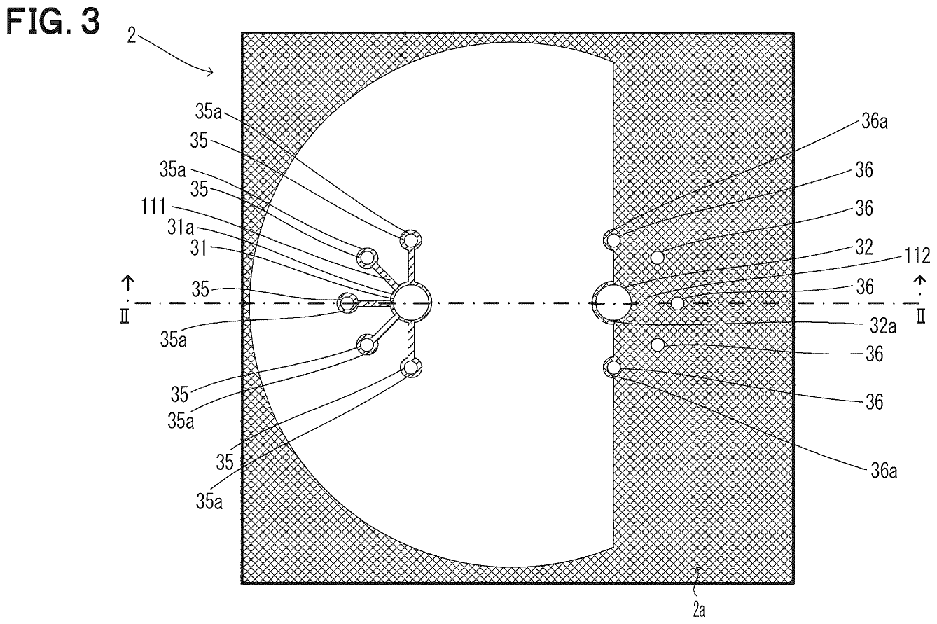

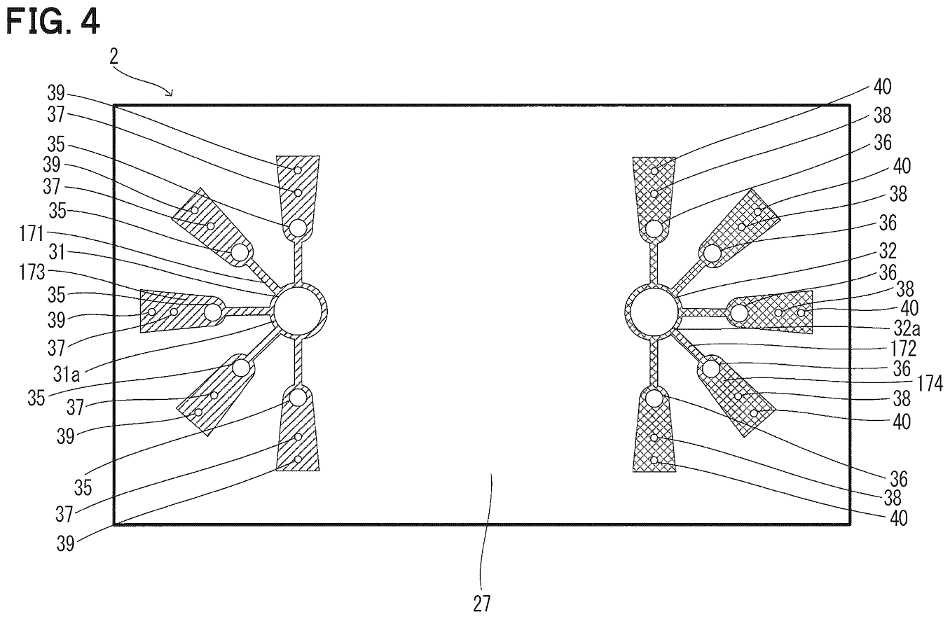

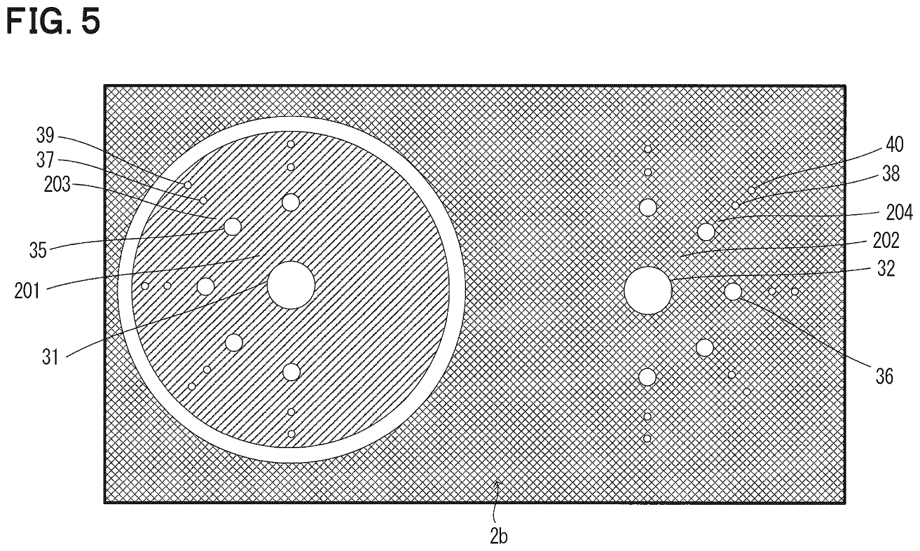

As shown in FIG. 2, FIG. 3, FIG. 4, and FIG. 5, a plurality of positive electrode through vias 35 are formed around the positive electrode terminal through hole 31, and a plurality of negative electrode through vias 36 are formed around the negative electrode terminal through hole 32.

The positive electrode through vias 35 and the negative electrode through vias 36 are formed so as to penetrate through the dielectric layers 21 to 29. A conductor 35a is formed over the entire inner circumferential surface of each of the positive electrode through vias 35. In addition, a conductor 36a is formed over the entire inner circumferential surface of each of the negative electrode through vias 36. Hereinafter, the conductor 35a and the conductor 36a will be referred to as the positive electrode through via conductor 35a and the negative electrode through via conductor 36a, respectively.

As shown in FIG. 2 and FIG. 3, the conductive pattern layer 11 includes first positive electrode connection patterns 111 that connect the positive electrode terminal through hole conductor 31a and the positive electrode through via conductors 35a, and first negative electrode connection patterns 112 that connect the negative electrode terminal through hole conductor 32a and the negative electrode through via conductors 36a.

As shown in FIG. 2, the conductive pattern layer 12 includes first positive electrode connection patterns 121 that connect the positive electrode terminal through hole conductor 31a and the positive electrode through via conductors 35a, and first negative electrode connection patterns 122 that connect the negative electrode terminal through hole conductor 32a and the negative electrode through via conductors 36a.

The conductive pattern layers 13, 14, 15, 16, 17, 18, 19, 20 respectively include first positive electrode connection patterns 131, 141, 151, 161, 171, 181, 191, 201 that connect the positive electrode terminal through hole conductor 31a and the positive electrode through via conductors 35a, and first negative electrode connection patterns 132, 142, 152, 162, 172, 182, 192, 202 that connect the negative electrode terminal through hole conductor 32a and the negative electrode through via conductors 36a.

As shown in FIG. 2 and FIG. 4, a plurality of first positive electrode inner layer vias 37 are formed around the plurality of positive electrode through vias 35, and a plurality of first negative electrode inner layer vias 38 are formed around the plurality of negative electrode through vias 36. Furthermore, a plurality of second positive electrode inner layer vias 39 are formed around the plurality of first positive electrode inner layer vias 37, and a plurality of second negative electrode inner layer vias 40 are formed around the plurality of first negative electrode inner layer vias 38.

The plurality of first positive electrode inner layer vias 37 are arranged in a semicircle so as to surround the plurality of positive electrode through vias 35 arranged in a semicircle. The plurality of first negative electrode inner layer vias 38 are arranged in a semicircle so as to surround the plurality of negative electrode through vias 36 arranged in a semicircle.

The plurality of second positive electrode inner layer vias 39 are arranged in a semicircle so as to surround the plurality of first positive electrode inner layer vias 37 arranged in a semicircle. The plurality of second negative electrode inner layer vias 40 are arranged in a semicircle so as to surround the plurality of first negative electrode inner layer vias 38 arranged in a semicircle.

The first positive electrode inner layer vias 37 and the first negative electrode inner layer vias 38 penetrate through the dielectric layers 27, 28, and 29. A conductor 37a is formed over the entire inner circumferential surface of each of the first positive electrode inner layer vias 37. In addition, a conductor 38a is formed over the entire inner circumferential surface of each of the first negative electrode inner layer vias 38. Hereinafter, the conductor 37a and the conductor 38a will be referred to as a first positive electrode inner layer via conductor 37a and a first negative electrode inner layer via conductor 38a, respectively.

The second positive electrode inner layer vias 39 and the second negative electrode inner layer vias 40 penetrate through the dielectric layers 27, 28, and 29. A conductor 39a is formed over the entire inner circumferential surface of each of the second positive electrode inner layer vias 39. In addition, a conductor 40a is formed over the entire inner circumferential surface of each of the second negative electrode inner layer vias 40. Hereinafter, the conductor 39a and the conductor 40a will be referred to as a second positive electrode inner layer via conductor 39a and a second negative electrode inner layer via conductor 40a, respectively.

The conductive pattern layers 17, 18, 19, 20 respectively include second positive electrode connection patterns 173, 183, 193, 203 that connect the positive electrode through via conductor 35a, the first positive electrode inner layer via conductors 37a, and the second positive electrode inner layer via conductors 39a, and second negative electrode connection patterns 174, 184, 194, 204 that connect the negative electrode through via conductor 36a, the first negative electrode inner layer via conductors 38a, and the second negative electrode inner layer via conductors 40a.

The printed circuit board 2 configured in this manner includes the first dielectric layer 21 to the ninth dielectric layer 29, the first conductive pattern layer 11 to the tenth conductive pattern layer 20, the positive electrode terminal through hole 31, the positive electrode through vias 35, and the first positive electrode inner layer vias 37.

The positive electrode terminal through hole 31 penetrates through the first dielectric layer 21 to the ninth dielectric layer 29, and has the inner circumferential surface on which the positive electrode terminal through hole conductor 31a is disposed. The positive electrode terminal 101 of the capacitor 100 is inserted into the positive electrode terminal through hole 31.

Each of the positive electrode through vias 35 penetrates through the first dielectric layer 21 to the ninth dielectric layer 29, and has the inner circumferential surface on which the positive electrode through via conductor 35a is disposed. The positive electrode through vias 35 are connected to the positive electrode terminal through hole 31 with at least one of the first conductive pattern layer 11 to the ninth conductive pattern layer 19.

Each of the first positive electrode inner layer vias 37 penetrates through each dielectric layer from the seventh dielectric layer 27 to the ninth dielectric layer 29, and has the inner circumferential surface on which the first positive electrode inner layer via conductor 37a is disposed.

The positive electrode through vias 35 and the first positive electrode inner layer vias 37 are connected to each other with the conductive pattern layers 17, 18, and 19. The printed circuit board 2 described above has the first positive electrode inner layer vias 37 connected to the positive electrode through vias 35, thereby increasing the number of paths for conducting heat between the first conductive pattern layer 11 and the tenth conductive pattern layer 20, and improving the thermal efficiency of the printed circuit board 2.

Furthermore, in the printed circuit board 2, the first positive electrode inner layer vias 37 penetrate through each dielectric layer from any one of dielectric layers selected from the second dielectric layer 22 to ninth dielectric layer 29 to the ninth dielectric layer 29. Therefore, in the printed circuit board 2, the number of dielectric layers through which the first positive electrode inner layer vias 37 penetrate and the arrangement of the first positive electrode inner layer vias 37 can be changed depending on the wiring pattern in the printed circuit board 2. Accordingly, the printed circuit board 2 can ensure the freedom in wiring pattern arrangement.

As described above, the printed circuit board 2 can improve the thermal efficiency of the printed circuit board while ensuring the freedom in wiring pattern arrangement. The printed circuit board 2 also has the second positive electrode inner layer vias 39 disposed opposite the positive electrode through vias 35 across the first positive electrode inner layer vias 37. Each of the second positive electrode inner layer vias 39 penetrates through each dielectric layer from the seventh dielectric layer 27 to the ninth dielectric layer 29 and has the inner circumferential surface on which the second positive electrode inner layer via conductor 39a is disposed.

The printed circuit board 2 described above can further increase the paths for conducting heat between the first conductive pattern layer 11 and the tenth conductive pattern layer 20, thereby further improving the thermal efficiency of the printed circuit board 2.

In the embodiment described above, the capacitor 100 corresponds to a mounted component, the positive electrode terminal 101 corresponds to a terminal, the positive electrode terminal through hole 31 corresponds to a through hole, the positive electrode terminal through hole conductor 31a corresponds to a through hole conductor, the positive electrode through vias 35 correspond to through vias, and the positive electrode through via conductors 35a correspond to through via conductors.

In addition, the first positive electrode inner layer vias 37 corresponds to inner layer vias, the first positive electrode inner layer via conductors 37a correspond to inner layer via conductors, the second positive electrode inner layer vias 39 correspond to additional inner layer vias, and the second positive electrode inner layer via conductors 39a correspond to additional inner layer via conductors.

### Second Embodiment

Hereinafter, a second embodiment according to the present disclosure will be described with reference to the drawings. In the second embodiment, portions different from those of the first embodiment will be described. Common configurations are denoted by the same reference numerals.

The electronic control device 1 of the second embodiment differs from the first embodiment in that the shapes of the first positive electrode inner layer vias 37, the first negative electrode inner layer vias 38, the second positive electrode inner layer vias 39, and the second negative electrode inner layer vias 40 are changed.

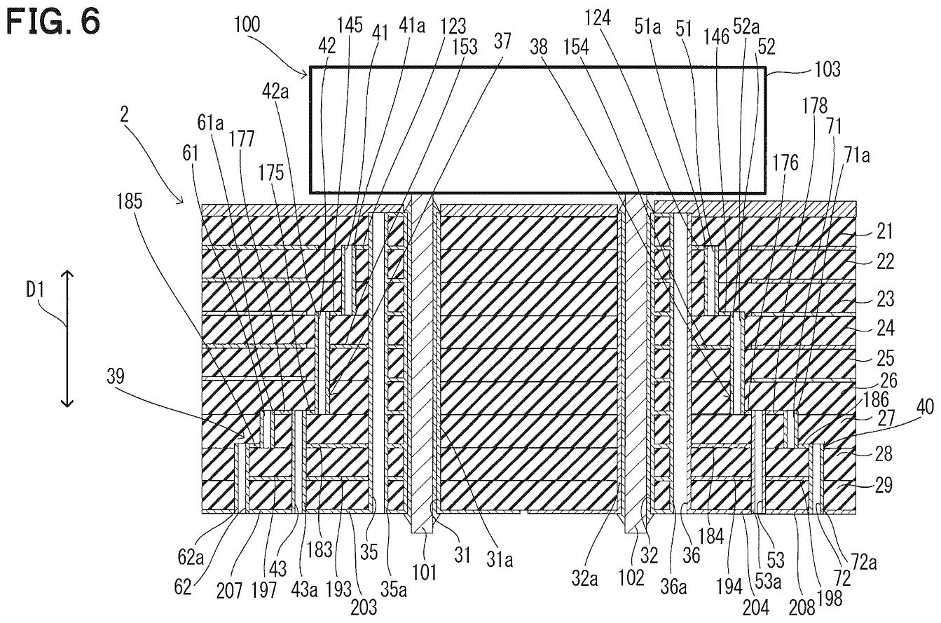

As shown in FIG. 6, each of the first positive electrode inner layer vias 37 includes split vias 41, 42, and 43 and third positive electrode connection patterns 145 and 175. The split via 41 penetrates through the dielectric layers 22 and 23. A conductor 41a is formed over the entire inner circumferential surface of the split via 41. The split via 42 penetrates through the dielectric layers 24 to 26. A conductor 42a is formed over the entire inner circumferential surface of the split via 42. The split via 43 penetrates through the dielectric layers 27 to 29. A conductor 43a is formed over the entire inner circumferential surface of the split via 43. Hereinafter, the conductors 41a, 42a, and 43a will be referred to as split via conductors 41a, 42a, and 43a, respectively.

The split via 41 is connected to the positive electrode through via 35 with a second positive electrode connection pattern 123. The split via 42 is connected to the positive electrode through via 35 with a second positive electrode connection pattern 153. The split via 43 is connected to the positive electrode through via 35 with second positive electrode connection patterns 183, 193, and 203.

The split via 41 and the split via 42 are arranged such that a distance between the split via 41 and the positive electrode terminal through hole 31 is shorter than a distance between the split via 42 and the positive electrode terminal through hole 31. Furthermore, the split via 42 and the split via 43 are arranged such that the distance between the split via 42 and the positive electrode terminal through hole 31 is shorter than a distance between the split via 43 and the positive electrode terminal through hole 31.

The conductive pattern layer 15 includes the third positive electrode connection pattern 145 that connects the split via conductor 41a and the split via conductor 42a. The conductive pattern layer 15 includes the third positive electrode connection pattern 175 that connects the split via conductor 42a and the split via conductor 43a.

Each of the first negative electrode inner layer via 38 includes split vias 51, 52, and 53 and third negative electrode connection patterns 146 and 176. The split via 52 penetrates through the dielectric layers 22 and 23. A conductor 51a is formed over the entire inner circumferential surface of the split via 51. The split via 52 penetrates through the dielectric layers 24 to 26. A conductor 52a is formed over the entire inner circumferential surface of the split via 52. The split via 53 penetrates through the dielectric layers 27 to 29. A conductor 53a is formed over the entire inner circumferential surface of the split via 53. Hereinafter, the conductors 51a, 52a, and 53a will be referred to as split via conductors 51a, 52a, and 53a, respectively.

The split via 51 is connected to the negative electrode through via 36 with a second negative electrode connection pattern 124. The split via 52 is connected to the negative electrode through via 36 with a second negative electrode connection pattern 154. The split via 53 is connected to the negative electrode through via 36 with second negative electrode connection patterns 184, 194, and 204.

The split via 51 and the split via 52 are arranged such that a distance between the split via 51 and the negative electrode terminal through hole 32 is shorter than a distance between the split via 52 and the negative electrode terminal through hole 32. Furthermore, the split via 52 and the split via 53 are arranged such that the distance between the split via 52 and the negative electrode terminal through hole 32 is shorter than a distance between the split via 53 and the negative electrode terminal through hole 32.

The conductive pattern layer 14 includes the third negative electrode connection pattern 146 that connects the split via conductor 51a and the split via conductor 52a. The conductive pattern layer 17 includes the third negative electrode connection pattern 176 that connects the split via conductor 52a and the split via conductor 53a.

Each of the second positive electrode inner layer vias 39 includes split vias 61 and 62 and a third positive electrode connection pattern 185. The split via 61 penetrates through the dielectric layer 27. A conductor 61a is formed over the entire inner circumferential surface of the split via 61. The split via 62 penetrates through the dielectric layers 28 and 29. A conductor 62a is formed over the entire inner circumferential surface of the split via 62. Hereinafter, the conductors 61a and 62a will be referred to as split via conductors 61a and 62a, respectively.

The split via 61 is connected to the split via 43 with a fourth positive electrode connection pattern 177. The split via 62 is connected to the split via 43 with fourth positive electrode connection patterns 197 and 207. The split via 61 and the split via 62 are arranged such that a distance between the split via 61 and the positive electrode terminal through hole 31 is shorter than a distance between the split via 62 and the positive electrode terminal through hole 31.

The conductive pattern layer 18 includes the third positive electrode connection pattern 185 that connects the split via conductor 61a and the split via conductor 62a. Each of the second negative electrode inner layer vias 38 includes split vias 71 and 72 and a third negative electrode connection pattern 186.

The split via 71 penetrates through the dielectric layer 27. A conductor 71a is formed over the entire inner circumferential surface of the split via 71. The split via 72 penetrates through the dielectric layers 28 and 29. A conductor 72a is formed over the entire inner circumferential surface of the split via 72. Hereinafter, the conductors 71a and 72a will be referred to as split via conductors 71a and 72a, respectively.

The split via 71 is connected to the split via 53 with a fourth positive electrode connection pattern 178. The split via 72 is connected to the split via 53 with fourth positive electrode connection patterns 198 and 208. The split via 71 and the split via 72 are arranged such that a distance between the split via 71 and the negative electrode terminal through hole 32 is shorter than a distance between the split via 72 and the negative electrode terminal through hole 32.

The conductive pattern layer 18 includes the third negative electrode connection pattern 186 that connects the split via conductor 71a and the split via conductor 72a. In the printed circuit board 2 configured in this manner, the first positive electrode inner layer vias 37 and the second positive electrode inner layer vias 39 are arranged such that the distance to the positive electrode terminal through hole 31 becomes shorter as the first positive electrode inner layer vias 37 and the second positive electrode inner layer vias 39 approach from the tenth conductive pattern layer 20 to the first conductive pattern layer 11. This allows the printed circuit board 2 to have greater freedom in wiring pattern arrangement in a portion adjacent to the mounting surface 2a on which the capacitor 100 is mounted.

Each of the first positive electrode inner layer vias 37 includes the plurality of split vias 41, 42, 43 that penetrate through at least one dielectric layer and also penetrate through different dielectric layers from each other. The split via 41 penetrates through the dielectric layers 22 and 23. The split via 42 penetrates through the dielectric layers 24 to 26. The split via 43 penetrates through the dielectric layers 27 to 29. Specifically, each of the first positive electrode inner layer vias 37 is formed in a non-linear shape along the laminating direction D1 by connecting the split vias 41, 42, 43 with the third positive electrode connection patterns 145 and 175.

Each of the second positive electrode inner layer vias 39 includes the plurality of split vias 61, 62 penetrating at least one dielectric layer. The split via 61 penetrates through the dielectric layer 27. The split via 62 penetrates through the dielectric layers 28 and 29. Specifically, each of the second positive electrode inner layer vias 39 is formed in a non-linear shape along the laminating direction D1 by connecting the split vias 61 and 62 with the third positive electrode connection pattern 185.

In the printed circuit board 2 having the above-described configuration, the arrangement of the split vias 41, 42, 43 and the split vias 61, 62 can be changed to change the shapes of the first positive electrode inner layer vias 37 and the second positive electrode inner layer vias 39 according to the wiring pattern within the printed circuit board 2, thereby ensuring the freedom of circuit design.

Although embodiments of the present disclosure have been described above, the present disclosure is not limited to the above-described embodiments, and various modifications can be made.

### First Modification

In the above-described embodiments, the first conductive pattern layer 11 to the tenth conductive pattern layer 20 are provided, but the number of conductive pattern layers may be three or greater. In other words, the printed circuit board 2 may include the first conductive pattern layer 11 to an Nth conductive pattern layer, where N is an integer that is greater than or equal to three.

### Second Modification

In the above-described embodiments, examples in which the capacitor 100 is mounted on the printed circuit board 2 have been described. However, the mounted component mounted on the printed circuit board 2 is not limited to the capacitor 100, and may be any electronic component having a terminal that is inserted into a through hole.

### Third Modification

In the first embodiment, the first positive electrode inner layer vias 37, the first negative electrode inner layer vias 38, the second positive electrode inner layer vias 39, and the second negative electrode inner layer vias 40 penetrate through the dielectric layers 27 to 29. However, the first positive electrode inner layer vias 37, the first negative electrode inner layer vias 38, the second positive electrode inner layer vias 39, and the second negative electrode inner layer vias 40 may be configured to penetrate through each dielectric layer from any one of the dielectric layers 22 to 29 to the dielectric layer 29. For example, the first positive electrode inner layer vias 37, the first negative electrode inner layer vias 38, the second positive electrode inner layer vias 39, and the second negative electrode inner layer vias 40 may penetrate through the dielectric layers 22 to 29. In other words, the inner layer via may penetrate through each dielectric layer from an Mth dielectric layer to the (N-1)th dielectric layer in the plurality of dielectric layers, where M is an integer that is greater than or equal to two and less than or equal to (N−1), and the additional inner layer via may penetrate through each dielectric layer from an Lth dielectric layer to the (N-1)th dielectric layer in the plurality of dielectric layers, where L is an integer that is greater than equal to two and less than or equal to (N−1).

A plurality of functions belonging to one configuration element in the above-described embodiments may be implemented by a plurality of configuration elements, or one function belonging to one configuration element may be implemented by a plurality of configuration elements. A plurality of functions belonging to a plurality of configuration elements may be implemented by one configuration element, or one function implemented by a plurality of configuration elements may be implemented by one configuration element. A part of the configuration of the above-described embodiments may be omitted. At least a part of the configuration of the above-described embodiments may be added to or replaced with the configuration of another embodiment.

What is claimed is:

1. A printed circuit board comprising:
a plurality of dielectric layers from a first dielectric layer to an (N-1)th dielectric layer, where N is an integer that is greater than equal to three;
a plurality of conductive pattern layers from a first conductive pattern layer to an Nth conductive pattern layer alternately laminated with the plurality of dielectric layers in such a manner that the first conductive pattern layer is disposed above the first dielectric layer and the (N-1)th dielectric layer is disposed above the Nth conductive pattern layer;
a through hole penetrating through the plurality of dielectric layers from the first dielectric layer to the (N-1)th dielectric layer, having an inner circumferential surface on which a through hole conductor is disposed, and into which a terminal of a mounted component is to be inserted in a state where the mounted component is mounted above the first conductive pattern layer;
a through via penetrating through the plurality of dielectric layers from the first dielectric layer to the (N-1)th dielectric layer, having an inner circumferential surface on which a through via conductor is disposed, and connected to the through hole with at least one conductive pattern layer that is selected from the first conductive pattern layer to an (N-1)th conductive pattern layer in the plurality of conductive pattern layers; and
an inner layer via penetrating through each dielectric layer from an Mth dielectric layer to the (N-1)th dielectric layer in the plurality of dielectric layers, where M is an integer that is greater than or equal to two and less than or equal to (N-1), and having an inner circumferential surface on which an inner layer via conductor is disposed, wherein
the through via and the inner layer via are connected to each other with at least one conductive pattern layer that is selected from an Mth conductive pattern layer to the (N-1)th conductive pattern layer in the plurality of conductive pattern layers.

2. The printed circuit board according to claim 1, further comprising
an additional inner layer via disposed opposite the through via across the inner layer via, penetrating through each dielectric layer from an Lth dielectric layer to the (N-1)th dielectric layer in the plurality of dielectric layers, where L is an integer that is greater than or equal to two and less than or equal to (N−1), and having an inner circumferential surface on which an additional inner layer via conductor is disposed.

3. The printed circuit board according to claim 2, wherein
at least one of the inner layer via and the additional inner layer via is disposed such that a distance to the through hole becomes shorter as the at least one of the inner layer via and the additional inner layer via approaches from the Nth conductive pattern layer to the first conductive pattern layer.

4. The printed circuit board according to claim 2, wherein
at least one of the inner layer via and the additional inner layer via includes a plurality of split vias each penetrating through at least one dielectric layer in the plurality of dielectric layers.

5. The printed circuit board according to claim 4, wherein
the at least one of the inner layer via and the additional inner layer via is formed in a non-linear shape along a laminating direction in which the plurality of dielectric layers are laminated by connecting the plurality of split vias with at least one conductive pattern layer in the plurality of conductive pattern layers.

6. An electronic control device comprising a mounted component and a printed circuit board on which the mounted component is mounted, wherein the printed circuit board includes:
a plurality of dielectric layers from a first dielectric layer to an (N-1)th dielectric layer, where N is an integer that is greater than or equal to three;
a plurality of conductive pattern layers from a first conductive pattern layer to an Nth conductive pattern layer alternately laminated with the plurality of dielectric layers in such a manner that the first conductive pattern layer is disposed above the first dielectric layer and the (N-1)th dielectric layer is disposed above the Nth conductive pattern layer;
a through hole penetrating through the plurality of dielectric layers from the first dielectric layer to the (N-1)th dielectric layer, having an inner circumferential surface on which a through hole conductor is disposed, and into which a terminal of the mounted component is inserted in a state where the mounted component is mounted above the first conductive pattern layer;
a through via penetrating through the plurality of dielectric layers from the first dielectric layer to the (N-1)th dielectric layer, having an inner circumferential surface on which a through via conductor is disposed, and connected to the through hole with at least one conductive pattern layer that is selected from the first conductive pattern layer to an (N-1)th conductive pattern layer in the plurality of conductive pattern layers; and
an inner layer via penetrating through each dielectric layer from an Mth dielectric layer to the (N-1)th dielectric layer in the plurality of dielectric layers, where M is an integer that is greater than or equal to two and less than or equal to (N-1), and having an inner circumferential surface on which an inner layer via conductor is disposed, and
the through via and the inner layer via are connected to each other with at least one conductive pattern layer that is selected from an Mth conductive pattern layer to the (N-1)th conductive pattern layer in the plurality of conductive pattern layers.

7. The electronic control device according to claim 6, further comprising
an additional inner layer via disposed opposite the through via across the inner layer via, penetrating through each dielectric layer from an Lth dielectric layer to the (N-1)th dielectric layer in the plurality of dielectric layer, where L is an integer that is greater than equal to two and less than or equal to (N-1), and having an inner circumferential surface on which an additional inner layer via conductor is disposed.

8. The electronic control device according to claim 7, wherein
at least one of the inner layer via and the additional inner layer via is disposed such that a distance to the through hole becomes shorter as the at least one of the inner layer via and the additional inner layer via approaches from the Nth conductive pattern layer to the first conductive pattern layer.

9. The electronic control device according to claim 7, wherein
at least one of the inner layer via and the additional inner layer via includes a plurality of split vias each penetrating through at least one dielectric layer in the plurality of dielectric layers.

10. The electronic control device according to claim 9, wherein
the at least one of the inner layer via and the additional inner layer via is formed in a non-linear shape along a laminating direction in which the plurality of dielectric layers are laminated by connecting the plurality of split vias with at least one conductive pattern layer in the plurality of conductive pattern layers.
